(19) United States
(12) Patent Application Publication
(10) Pub. No.: US 2025/0374481 A1
(43) Pub. Date: Dec. 4, 2025

(54) JOINT, SERVER AND COMPUTING SYSTEM

(71) Applicant: Fulian Precision Electronics (Tianjin) Co., LTD., Tianjin (CN)

(72) Inventors: HSIAO-HSUAN CHANG, New Taipei (TW); CHANG-JU WU, New Taipei (TW)

(21) Appl. No.: 18/950,374

(22) Filed: Nov. 18, 2024

(30) Foreign Application Priority Data
May 31, 2024 (CN) 202410701418.9

(51) Int. Cl. H05K 7/20

(52) U.S. Cl. CPC H05K 7/20272; H05K 7/20772

(57) ABSTRACT

A joint for offsetting manufacturing tolerance comprises a base, a plug connector, a core-stem, a check valve. The base defines a spherical cavity, an opening, and an outlet. The plug connector comprises a ball head rotatably placed in the spherical cavity and a tube extending through the opening, and the plug connector defines a tunnel communicated with the outlet. The core-stem is positioned in the tunnel. The check valve comprises a block and a spring. The block is configured for blocking a loop-inlet formed between the core-stem and the tube, when a plug is inserted into the tube, the plug pushes the block out of the loop-inlet to communicate the plug with the tunnel, when the plug is pulled out of the tube, the spring pushes the block back into the loop-inlet to block the loop-inlet. A server and a computing system with the joint is also disclosed.

### FIELD

The disclosure herein generally relates to information computing systems, and more particularly relates to a joint, a server, and a computing system.

### BACKGROUND

When a server is installed in a rack, a plug connector behind the server needs to be connected to a plug on the rack, so that the rack can provide coolant to the server to cool the server. However, due to tolerances in the manufacturing process, the plug connector of the server and the plug of the rack are sometimes misaligned, resulting in the plug connector of the server and the plug of the rack unable to connect.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an embodiment of a joint according to the present disclosure.

FIG. 2 is a section view of the joint in FIG. 1 in section line II-II, showing a loop-inlet blocked by a block.

FIG. 3 is a section view of the joint in FIG. 2, showing the block moved out of the loop-inlet.

FIG. 4 is an exploded view of the joint shown in FIG. 1.

FIG. 5 is an exploded view of a base shown in FIG. 1.

FIG. 6 is a section view of a plug connector shown in FIG. 2.

FIG. 7 is an isometric view of a core-stem shown in FIG. 4.

FIG. 8 is an isometric view of a block shown in FIG. 4.

FIG. 9 is a diagram view of an embodiment of a computing system according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

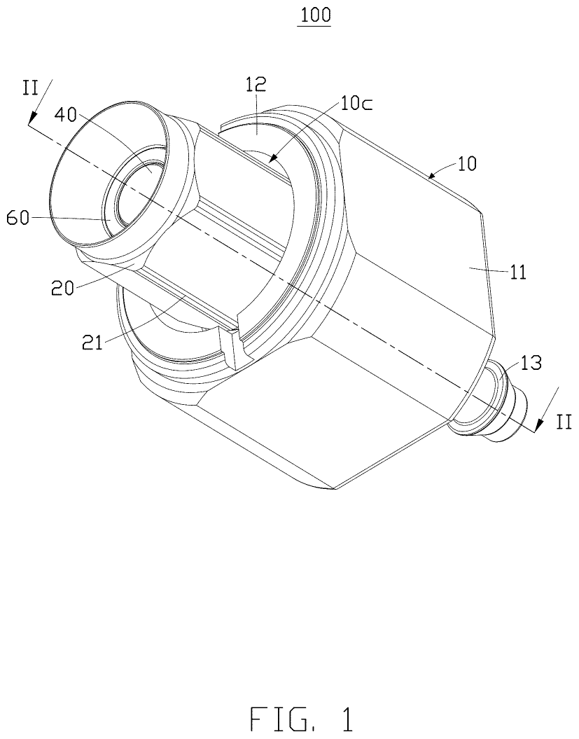

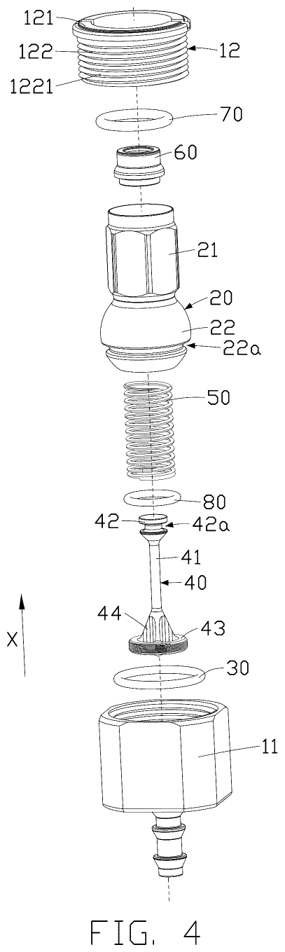

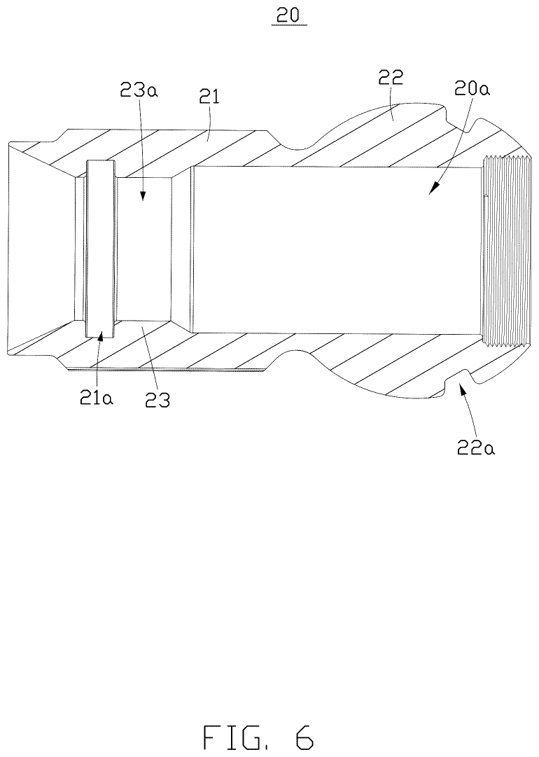

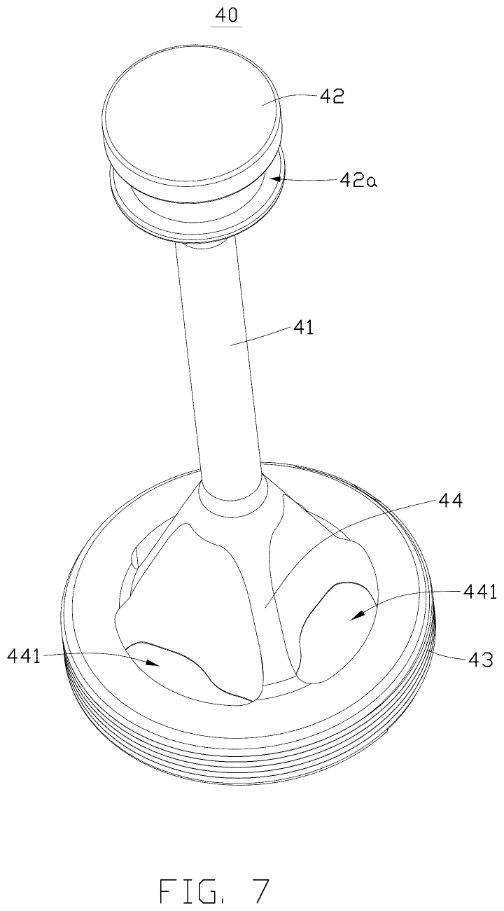

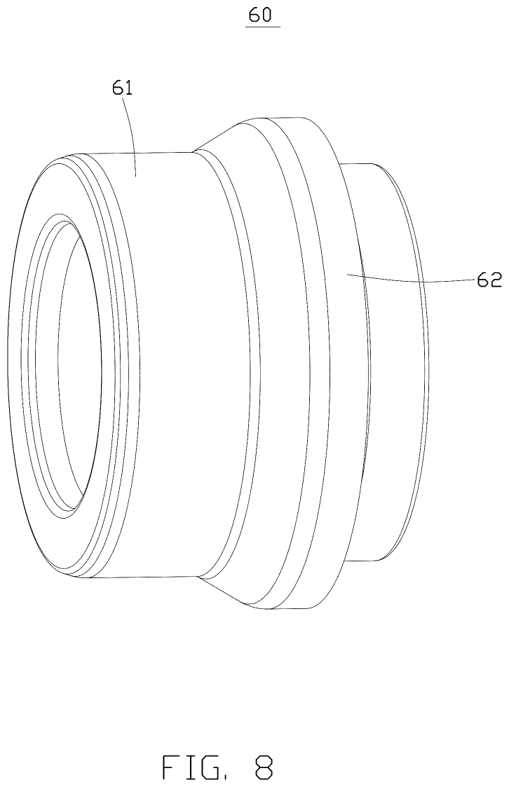

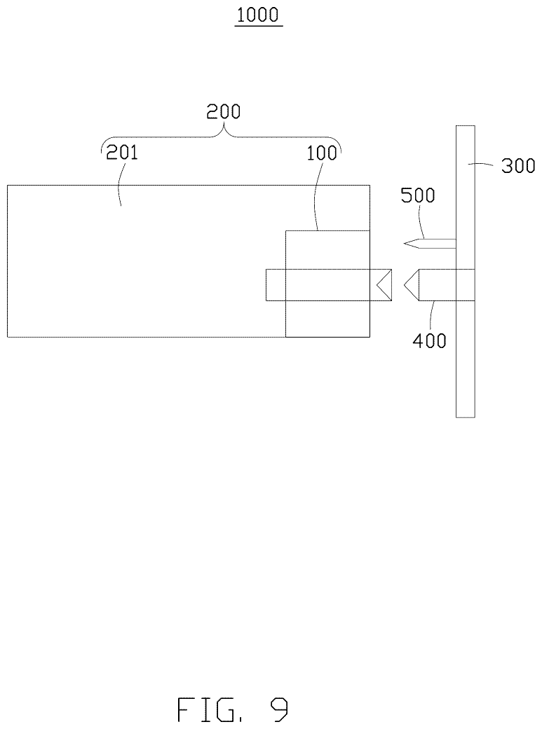

As shown in FIG. 1 to FIG. 9, a computing system 1000 in an embodiment includes a rack 300 and a plurality of servers 200. The plurality of servers 200 can be installed into the rack 300 in layers. The rack 300 includes a plurality of plugs 400, and there is at least one plug 400 in each layer. Each server 200 has a chassis 201 and a joint 100 in the back. When one of the plurality of servers 200 is installed into the rack 300, the joint 100 needs to be connected to the plug 400 in the same layer, so that the rack 300 can provide coolant to the server 200 to cool the server 200. Usually, there are two plugs 400 in each layer in the rack 300, and there are two joints 100 in the back of each server 200, when the server 200 is installed into the rack 300, the two joints 100 are connected to the two plugs 400 one-to-one, so that the coolant can be circulated between the server 200 and the rack 300.

The rack 300 further includes a guiding pin 500 in each layer. Each server 200 has a guiding hole (not shown in FIGs) in the back. When a server 200 is installed into the rack 300, the guiding pin 500 is inserted into the guiding hole to guide the movement of the server 200. Normally, when guiding pin 500 is aligned with the guiding hole, the joint 100 should be aligned with the plug 400, to ensure that the server 200 is installed properly.

However, sometimes when guiding pin 500 is aligned with the guiding hole, the plug connector 10 is not aligned with the plug 400 due to manufacturing tolerances for example, resulting in the joint 100 being unable to connect the plug 400.

As shown in FIG. 1 to FIG. 3, in some embodiments, to solve the problem mentioned above, the joint 100 includes a base 10, a plug connector 20, a core-stem 40, a and a check valve. The base 10 has a spherical cavity 10a, an opening 10c, and an outlet 10b, the opening 10c and the outlet 10b are located on two opposite sides of the base 10, respectively, the opening 10c and the outlet 10b are communicated with the spherical cavity 10a. The plug connector 20 includes a ball head 22 and a tube 21, the ball head 22 is rotatably placed in the spherical cavity 10a, and the tube 21 extends through the opening 10c and the tube 21 is used to connect the plug 400. The plug connector 20 has a tunnel 20a that passes through the ball head 22 and the tube 21, the tunnel 20a is communicated with the spherical cavity 10a and the outlet 10b, the outlet 10b is communicated to a coolant circuit in the server 200. The core-stem 40 and the check valve are positioned in the tunnel 20a. The check valve includes a block 60 and a spring 50. A diameter of the opening 10c is smaller than a diameter of the spherical cavity 10a, but the diameter of the opening 10c is larger than a diameter of the tube 21, so that the tube 21 can swing in the opening 10c around the ball center by the ball head 22 rotating around the ball center. When a server 200 is installed into the rack 300, the server 200 moves along a direction parallel to an axis of the plug 400, if the plug 400 is aligned with the tube 21, the plug 400 will insert into the tube 21 smoothly; but if the plug 400 is not aligned with the tube 21, because the tube 21 is swingable, the plug 400 will force the tube 21 to swing when the plug 400 begins to insert into the tube 21, to force the tube 21 to be aligned with the plug 400 during the plug 400 inserting into the tube 21, so that the plug 400 is able to will insert into the tube 21 properly, realizing a function of auto-calibration.

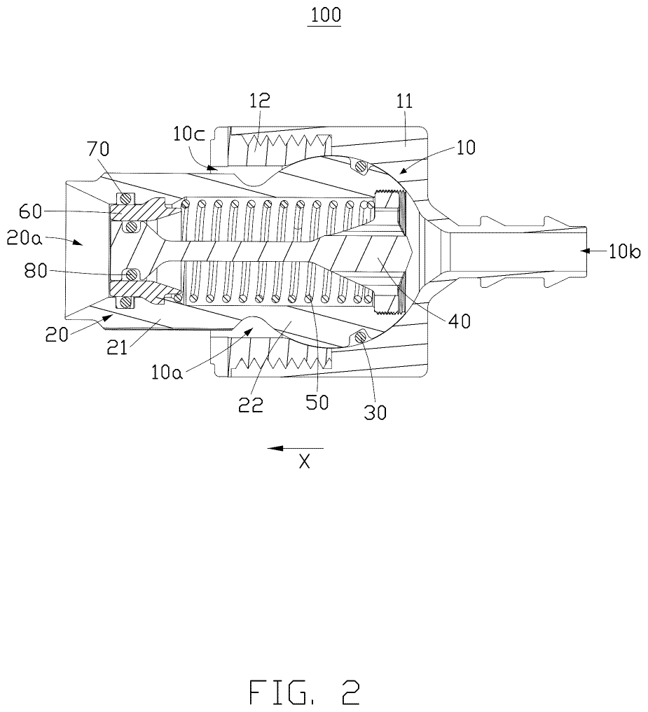

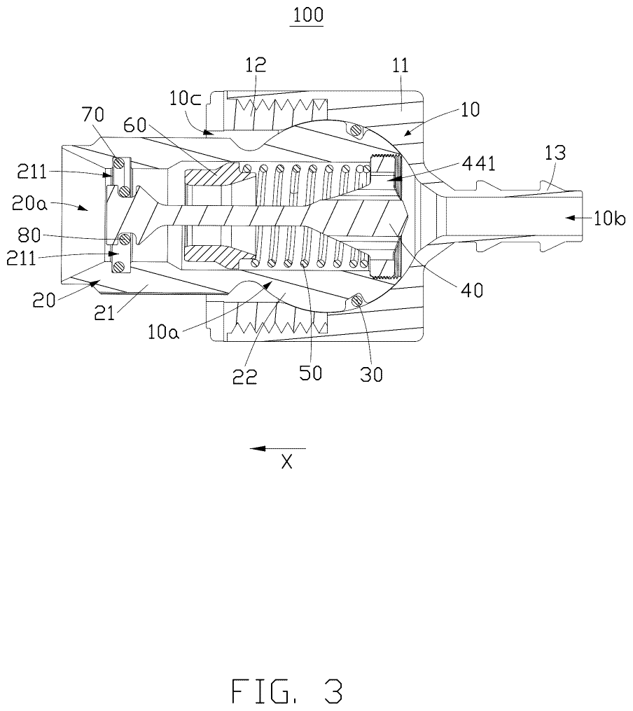

Furthermore, the block 60 surrounds the core-stem 40 and the block 60 is used for blocking a loop-inlet 211 formed between the core-stem 40 and the tube 21. As shown in FIG. 2 and FIG. 3, when a plug 400 is inserted into the tube 21 (when the server 200 is installed into the rack 300), the plug 400 pushes the block 60 (to the right in FIG. 2 and FIG. 3) out of the loop-inlet 211 to communicate the plug 400 with the tunnel 20a, so that the coolant can flow through the plug 400, the tube 21, and the outlet 10b into the coolant circuit in the server 200, and meanwhile the spring 50 is compressed. When the plug 400 is pulled out of the tube 21 (when the server 200 is removed from the rack 300), the spring 50 pushes the block 60 back into the loop-inlet 211 (to the left, direction X in FIG. 2 and FIG. 3) to block the loop-inlet 211, avoiding the coolant in the circuit in the server 200 from flowing out through the loop-inlet 211.

In some embodiments, the ball head 22 has a first seal-ring groove 22a, the first seal-ring groove 22a is used for positioning a first seal-ring 30, the first seal-ring 30 is compressed by an interior surface of the base 10 and an exterior surface of the ball head 22, the first seal-ring 30 is used for sealing the gap between the exterior surface of the ball head 22 and the interior surface of the spherical cavity 10a in the base 10, avoiding the coolant from flowing out through opening 10c.

In some embodiments, the base 10 includes a socket 11 and a cover 12, the outlet 10b is formed by the socket 11, the opening 10c is formed by the cover 12, the spherical cavity 10a is formed by the socket 11 and the cover 12. The socket 11 and the cover 12 are used for assembling the ball head 22 into the base 10.

In some embodiments, the core-stem 40 has a stem-ring 43, a stem-rod 41, a stem-head 42, and a plurality of stem-ribs 44. The stem-ring 43 is positioned on the ball head 22. The stem-rod 41 extends along an axis of the tube 21, an end of the stem-rod 41 is connected to the stem-ring 43 by the plurality of stem-ribs 44, another end of the stem-rod 41 is connected to the stem-head 42. A gap 441 is formed between each adjacent two ones of the plurality of stem-ribs 44, and the coolant flows through the gap 441. The loop-inlet 211 is formed between the stem-head 42 and the tube 21, the block 60 surrounds the stem-head 42 when blocking the loop-inlet 211, the block 60 surrounds the stem-rod 41 when being pushed out of the loop-inlet 211.

In some embodiments, the tube 21 has a second seal-ring groove 21a in the loop-inlet 211, the second seal-ring groove 21a is used for positioning a second seal-ring 70. The stem-head 42 has a third seal-ring groove 42a in the loop-inlet 211, the third seal-ring groove 42a is used for positioning a third seal-ring 80. When the block 60 blocks the loop-inlet 211, the second seal-ring 70 seals a gap between the block 60 and the tube 21, and the third seal-ring 80 seals a gap between the block 60 and the stem-head 42.

In some embodiments, an axis of the stem-ring 43, an axis of the stem-rod 41, an axis of the stem-head 42, and an axis of the tube 21 are coincided.

In some embodiments, the socket 11 further includes a pipe 13, the pipe 13 is communicated with the tunnel 20a, and the outlet 10b is formed on an end of the pipe 13 away from the socket 11.

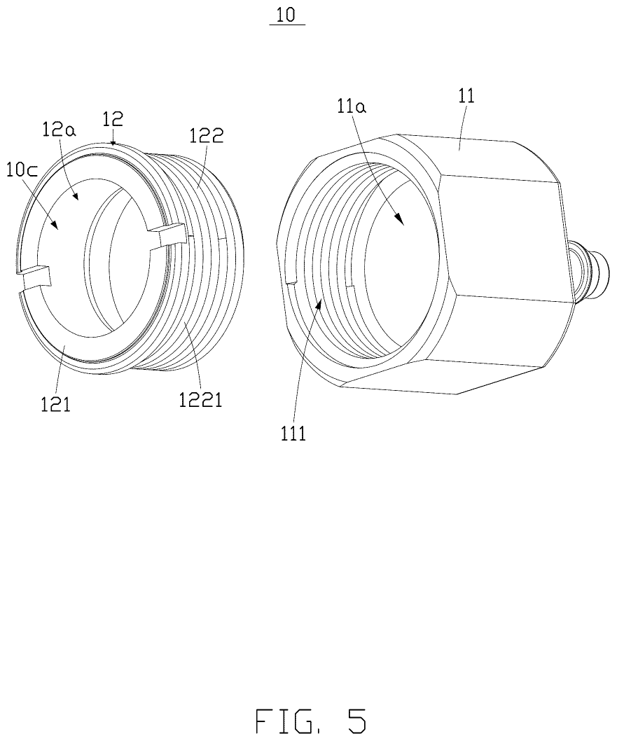

In some embodiments, as shown in FIG. 2 and FIG. 5, the socket 11 has a slot 11a and a screw thread 111 in the slot 11a. The cover 12 includes first ring part 121 [symbol] second ring part 122, the cover 12 has a first hole 12a, the opening 10c forms at an end of the first hole 12a away from the socket 11, the second ring part 122 has a screw thread 1221. The screw thread 111 and the screw thread 1221 screw together to assemble socket 11 and the cover 12.

In some embodiments, the tube 21 has a first protruded ring 23 in the tunnel 20a, a narrowed opening 23a is formed at first protruded ring 23, the stem-head 42 is placed in the narrowed opening 23a, the loop-inlet 211 is formed between the first protruded ring 23 and the stem-head 42. When the block 60 blocks the loop-inlet 211, the block 60 is placed in the narrowed opening 23a.

In some embodiments, the block 60 includes a main body 61 and a second protruded ring 62, the second protruded ring 62 surrounds the main body 61. When the block 60 blocks the loop-inlet 211, the main body 61 is in the narrowed opening 23a, the second protruded ring 62 is compressed by the first protruded ring 23 and the main body 61, to better seal the loop-inlet 211.

In some embodiments, the block 60 is made of rubber.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A joint comprising:
a base defining a spherical cavity, an opening, and an outlet;
a plug connector comprising a ball head rotatably placed in the spherical cavity and a tube extending through the opening, and the plug connector defining a tunnel communicating with the outlet;
a core-stem positioned in the tunnel; and
a check valve comprising a block and a spring,
wherein a diameter of the opening is smaller than a diameter of the spherical cavity and the diameter of the opening is larger than a diameter of the tube, the block surrounds the core-stem and is configured for blocking a loop-inlet formed between the core-stem and the tube, when a plug is inserted into the tube, the plug pushes the block out of the loop-inlet to communicate the plug with the tunnel and the spring is compressed, and when the plug is pulled out of the tube, the spring pushes the block back into the loop-inlet to block the loop-inlet.

2. The joint of claim 1, wherein the ball head defines a first seal-ring groove, the first seal-ring groove is configured for positioning a first seal-ring, the first seal-ring is compressed by an interior surface of the base and an exterior surface of the ball head.

3. The joint of claim 1, wherein the base comprises a socket and a cover, the outlet is formed by the socket, the opening is formed by the cover, the spherical cavity is formed by the socket and the cover.

4. The joint of claim 1, wherein the core-stem comprises a stem-ring, a stem-rod, a stem-head, and a plurality of stem-ribs, the stem-ring is positioned on the ball head, the stem-rod extends along an axis of the tube, an end of the stem-rod is connected to the stem-ring by the plurality of stem-ribs, another end of the stem-rod is connected to the stem-head, a gap is formed between each adjacent two stem-ribs of the plurality of stem-ribs, the loop-inlet is formed between the stem-head and the tube, the block surrounds the stem-head when blocking the loop-inlet, the block surrounds the stem-rod when being pushed out of the loop-inlet.

5. The joint of claim 4, wherein the tube defines a second seal-ring groove in the loop-inlet, the second seal-ring groove is configured for positioning a second seal-ring, the stem-head defines a third seal-ring groove in the loop-inlet, the third seal-ring groove is configured for positioning a third seal-ring, when the block blocks the loop-inlet, the second seal-ring seals a gap between the block and the tube, and the third seal-ring seals a gap between the block and the stem-head.

6. The joint of claim 4, wherein an axis of the stem-ring, an axis of the stem-rod, an axis of the stem-head, and an axis of the tube are coincided.

7. The joint of claim 3, wherein the socket further comprises a pipe, the pipe is communicated with the tunnel, and the outlet is formed on an end of the pipe away from the socket.

8. A server comprising:
a chassis; and
a joint located on the chassis, the joint comprising:
a base defining a spherical cavity, an opening, and an outlet;
a plug connector comprising a ball head rotatably placed in the spherical cavity and a tube extending through the opening, and the plug connector defining a tunnel communicated with the outlet;
a core-stem positioned in the tunnel; and
a check valve comprising a block and a spring;
wherein a diameter of the opening is smaller than a diameter of the spherical cavity and the diameter of the opening is larger than a diameter of the tube, the block surrounds the core-stem and is configured for blocking a loop-inlet formed between the core-stem and the tube, when a plug is inserted into the tube, the plug pushes the block out of the loop-inlet to communicate the plug with the tunnel and the spring is compressed, and when the plug is pulled out of the tube, the spring pushes the block back into the loop-inlet to block the loop-inlet.

9. The server of claim 8, wherein the ball head defines a first seal-ring groove, the first seal-ring groove is configured for positioning a first seal-ring, the first seal-ring is compressed by an interior surface of the base and an exterior surface of the ball head.

10. The server of claim 8, wherein the base comprises a socket and a cover, the outlet is formed by the socket, the opening is formed by the cover, the spherical cavity is formed by the socket and the cover.

11. The server of claim 8, wherein the core-stem comprises a stem-ring, a stem-rod, a stem-head, and a plurality of stem-ribs, the stem-ring is positioned on the ball head, the stem-rod extends along an axis of the tube, an end of the stem-rod is connected to the stem-ring by the plurality of stem-ribs, another end of the stem-rod is connected to the stem-head, a gap is formed between each adjacent two stem-ribs of the plurality of stem-ribs, the loop-inlet is formed between the stem-head and the tube, the block surrounds the stem-head when blocking the loop-inlet, the block surrounds the stem-rod when being pushed out of the loop-inlet.

12. The server of claim 11, wherein the tube defines a second seal-ring groove in the loop-inlet, the second seal-ring groove is configured for positioning a second seal-ring, the stem-head defines a third seal-ring groove in the loop-inlet, the third seal-ring groove is configured for positioning a third seal-ring, when the block blocks the loop-inlet, the second seal-ring seals a gap between the block and the tube, and the third seal-ring seals a gap between the block and the stem-head.

13. The server of claim 11, wherein an axis of the stem-ring, an axis of the stem-rod, an axis of the stem-head, and an axis of the tube are coincided.

14. The server of claim 10, wherein the socket further comprises a pipe, the pipe is communicated with the tunnel, and the outlet is formed on an end of the pipe away from the socket.

15. A computing system comprising:
a rack comprising a plurality of plugs;
a plurality of servers placed in the rack, each of the plurality of servers comprising:
a chassis; and
a joint located on the chassis, the joint comprising:
a base defining a spherical cavity, an opening, and an outlet;
a plug connector comprising a ball head rotatably placed in the spherical cavity and a tube extending through the opening, and the plug connector defining a tunnel communicated with the outlet;
a core-stem positioned in the tunnel; and
a check valve comprising a block and a spring;
wherein a diameter of the opening is smaller than a diameter of the spherical cavity and the diameter of the opening is larger than a diameter of the tube, the block surrounds the core-stem and is configured for blocking a loop-inlet formed between the core-stem and the tube, when one of the plurality of plugs is inserted into the tube, the plug pushes the block out of the loop-inlet to communicate the plug with the tunnel and the spring is compressed, and when the plug is pulled out of the tube, the spring pushes the block back into the loop-inlet to block the loop-inlet.

16. The computing system of claim 15, wherein the ball head defines a first seal-ring groove, the first seal-ring groove is configured for positioning a first seal-ring, the first seal-ring is compressed by an interior surface of the base and an exterior surface of the ball head.

17. The computing system of claim 15, wherein the base comprises a socket and a cover, the outlet is formed by the socket, the opening is formed by the cover, the spherical cavity is formed by the socket and the cover.

18. The computing system of claim 15, wherein the core-stem comprises a stem-ring, a stem-rod, a stem-head, and a plurality of stem-ribs, the stem-ring is positioned on the ball head, the stem-rod extends along an axis of the tube, an end of the stem-rod is connected to the stem-ring by the plurality of stem-ribs, another end of the stem-rod is connected to the stem-head, a gap is formed between each adjacent two ones of the plurality of stem-ribs, the loop-inlet is formed between the stem-head and the tube, the block surrounds the stem-head when blocking the loop-inlet, the block surrounds the stem-rod when being pushed out of the loop-inlet.

19. The computing system of claim 18, wherein the tube defines a second seal-ring groove in the loop-inlet, the second seal-ring groove is configured for positioning a second seal-ring, the stem-head defines a third seal-ring groove in the loop-inlet, the third seal-ring groove is configured for positioning a third seal-ring, when the block blocks the loop-inlet, the second seal-ring seals a gap between the block and the tube, and the third seal-ring seals a gap between the block and the stem-head.

20. The computing system of claim 18, wherein an axis of the stem-ring, an axis of the stem-rod, an axis of the stem-head, and an axis of the tube are coincided, the socket further comprises a pipe, the pipe is communicated with the tunnel, and the outlet is formed on an end of the pipe away from the socket.
